(19) United States
(12) Patent Application Publication
(10) Pub. No.: US 2020/0091367 A1
(43) Pub. Date: Mar. 19, 2020

(54) PHOTOCOUPLER

(71) Applicants: Kabushiki Kaisha Toshiba, Tokyo (JP); Toshiba Electronic Devices & Storage Corporation, Tokyo (JP)

(72) Inventors: Hiroyuki Nakashima, Kitakyushu Fukuoka (JP); Mami Fujihara, Nakatsu Oita (JP); Masaru Koseki, Kitakyushu Fukuoka (JP); Yoshio Noguchi, Kitakyushu Fukuoka (JP)

(21) Appl. No.: 16/266,138

(22) Filed: Feb. 4, 2019

(30) Foreign Application Priority Data
Sep. 19, 2018 (JP) 2018-175244

(51) Int. Cl. H01L 31/167; H01L 31/02; H01L 25/16

(52) U.S. Cl. CPC H01L 31/167; H01L 25/167; H01L 31/02005

(57) ABSTRACT

A photocoupler of an embodiment comprises an insulating substrate, a semiconductor light receiving element, a semiconductor light emitting element, an input terminal, an output terminal, a resin molded body, and an antistripping material. The semiconductor light receiving element includes a light receiving region, a first electrode, and a second electrode. The semiconductor light emitting element includes a first and a second electrode, and emits emission light. The input terminal includes a first and a second conductive region. The output terminal includes a third and a fourth conductive region. The resin molded body is provided on the upper surface of the insulating substrate, the input terminal, the output terminal, the semiconductor light receiving element, and the semiconductor light emitting element. The antistripping material bonds a lower surface of the resin molded body to the input terminal and a lower surface of the resin molded body to the output terminal.

### CROSS-REFERENCE TO RELATED APPLICATIONS

This application is based upon and claims the benefit of priority from Japanese Patent Application No. 2018-175244, filed on Sep. 19, 2018; the entire contents of which are incorporated herein by reference.

### FIELD

Embodiments described herein relate generally to a photocoupler.

### BACKGROUND

The photocoupler includes a photocoupler or photorelay, and transmits signals in the state in which input and output terminals are electrically insulated from each other.

In the photocoupler, a semiconductor light receiving element and a semiconductor light emitting element are sealed with a resin molded body made of e.g. epoxy.

### BRIEF DESCRIPTION OF THE DRAWINGS

FIG. 1 is a schematic perspective view of a photocoupler according to a first embodiment;

FIG. 2A is a schematic plan view of the photocoupler according to the first embodiment, FIG. 2B is a schematic sectional view taken along line A-A, and FIG. 2C is a schematic sectional view taken along line B-B;

FIG. 3 is a schematic sectional view taken along line B-B illustrating a variation of the shape of the antistripping material;

FIG. 4 is a schematic sectional view taken along line B-B illustrating a second variation of the shape of the antistripping material;

FIG. 5 is a schematic perspective view of a photocoupler according to a comparative example;

FIG. 6A is a schematic sectional view taken along line C-C of the photocoupler according to the comparative example, and FIG. 6B is a partially enlarged schematic sectional view taken along line C-C; and

FIG. 7A is a schematic perspective view of a photocoupler according to a second embodiment, FIG. 7B is a schematic plan view before forming a sealing resin layer, FIG. 7C is a schematic sectional view taken along line D-D, and FIG. 7D is a schematic bottom view.

### DETAILED DESCRIPTION

In general, a photocoupler of an embodiment includes an insulating substrate, a semiconductor light receiving element, a semiconductor light emitting element, an input terminal, an output terminal, a resin molded body, and an antistripping material. The insulating substrate includes an upper surface, a first side surface, and a second side surface on opposite side of the first side surface. The semiconductor light receiving element is provided on the upper surface of the insulating substrate and includes a light receiving region, a first electrode, and a second electrode on its upper surface. The semiconductor light emitting element is provided on the light receiving region, includes a first electrode and a second electrode on its upper surface, and emits emission light toward the light receiving region. The input terminal includes a first conductive region and a second conductive region. The first conductive region is connected to the first electrode of the semiconductor light emitting element and is adjacent to the first side surface. The second conductive region is connected to the second electrode of the semiconductor light emitting element and is adjacent to the first side surface. The output terminal includes a third conductive region and a fourth conductive region. The third conductive region is connected to the first electrode of the semiconductor light receiving element and is adjacent to the second side surface. The fourth conductive region is connected to the second electrode of the semiconductor light receiving element and is adjacent to the second side surface. The resin molded body is provided on the upper surface of the insulating substrate, the input terminal, the output terminal, the semiconductor light receiving element, and the semiconductor light emitting element. The antistripping material bonds a lower surface of the resin molded body to the input terminal and the lower surface of the resin molded body to the output terminal. A part of the first conductive region adjacent to the first side surface is bonded to the resin molded body. A part of the second conductive region adjacent to the first side surface is bonded to the resin molded body. A part of the third conductive region adjacent to the second side surface is bonded to the resin molded body. A part of the fourth conductive region adjacent to the second side surface is bonded to the resin molded body.

Embodiments of the invention will now be described with reference to the drawings.

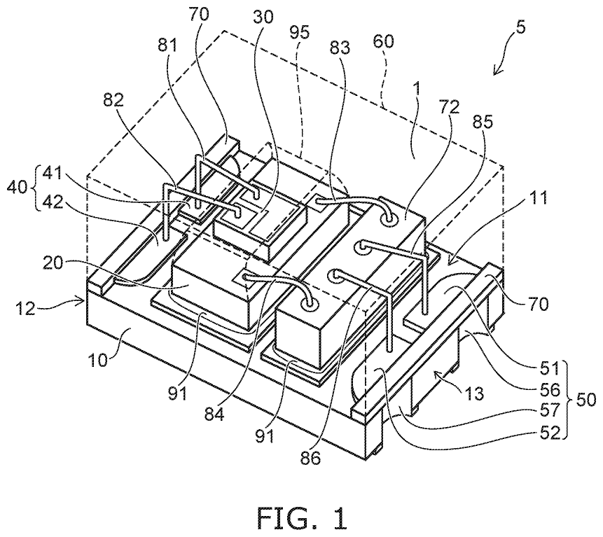

FIG. 1 is a schematic perspective view of a photocoupler according to a first embodiment.

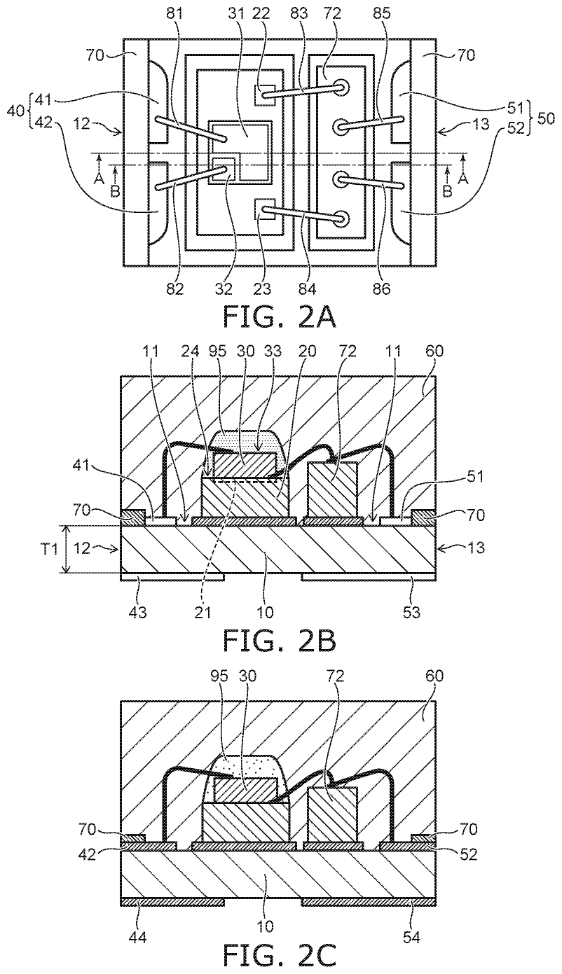

FIG. 2A is a schematic plan view of the photocoupler according to the first embodiment. FIG. 2B is a schematic sectional view taken along line A-A. FIG. 2C is a schematic sectional view taken along line B-B.

The photocoupler 5 includes an insulating substrate 10, a semiconductor light receiving element 20, a semiconductor light emitting element 30, an input terminal 40, an output terminal 50, a resin molded body 60, and an antistripping material 70. FIG. 1 shows a perspective view before forming the resin molded body 60 (shown by dashed lines) and an encapsulation resin 95.

The insulating substrate 10 includes e.g. a rectangular upper surface 11, a first side surface 12, and a second side surface 13 on the opposite side from the first side surface 12. The insulating substrate 10 contains e.g. glass fiber. The thickness T1 of the insulating substrate 10 can be e.g. 0.1-0.5 mm.

As shown in FIGS. 1 to 2C, the second side surface 13 of the insulating substrate 10 can be provided with a notch part. Likewise, the first side surface 12 of the insulating substrate 10 can also be provided with a notch part (not shown).

The semiconductor light receiving element 20 is provided on the upper surface 11 of the insulating substrate 10 and includes a light receiving region 21, a first electrode 22, and a second electrode 23 on its upper surface 24. The semiconductor light receiving element 20 can be a silicon p-n diode or phototransistor.

The semiconductor light emitting element 30 is provided on the light receiving region 21, includes a first electrode 31 and a second electrode 32 on its upper surface 33, and emits emission light toward the light receiving region 21. The semiconductor light emitting element contains e.g. GaAs-based or InGaAs-based material and emits infrared or near-infrared light. The surface of the semiconductor light emitting element 30 can be covered with an encapsulation resin 95 made of e.g. silicone resin.

The upper surface of the semiconductor light receiving element 20 and the lower surface of the semiconductor light emitting element 30 may be bonded with paste. The paste is translucent and insulative, and can be made of e.g. polyimide resin, epoxy resin, or silicone resin.

The input terminal 40 includes a first conductive region 41 and a second conductive region 42. The first conductive region 41 is connected to the first electrode 31 of the semiconductor light emitting element 30 and is adjacent to the first side surface 12. The second conductive region 42 is connected to the second electrode 32 of the semiconductor light emitting element 30 and is adjacent to the first side surface 12.

The output terminal 50 includes a third conductive region 51 and a fourth conductive region 52. The third conductive region 51 is connected to the first electrode 22 of the semiconductor light receiving element 20 through a semiconductor controlling element 72 and is adjacent to the second side surface 13. The fourth conductive region 52 is connected to the second electrode 23 of the semiconductor light receiving element 20 through the semiconductor controlling element 72 and is adjacent to the second side surface 13. The semiconductor controlling element 72 can be e.g. MOSFET. For instance, the MOSFET can include two common-source connected MOSFETs. The semiconductor controlling element 72 can be connected outside the photocoupler 5. In this case, the semiconductor light receiving element 20 may be connected directly to the output terminal 50.

The output terminal 50 includes a third conductive region 51 and a fourth conductive region 52 provided on the first surface 11. The third conductive region 51, the conductive region (via) 56 (FIG. 1) provided on the sidewall of the notch part of the second side surface 13, and the conductive region 53 provided on the back surface of the insulating substrate 10 constitute a continuous region. The fourth conductive region 52, the conductive region (via) 57 (FIG. 1) provided on the sidewall of the notch part of the second side surface 13, and the conductive region 54 (FIG. 2C) provided on the back surface of the insulating substrate 10 constitute a continuous region. The interconnect part such as a circuit substrate is bonded with a solder fillet formed on the conductive region (via) 56, 57 provided on the sidewall of the notch part. This facilitates confirming the bonding state of the solder material.

The input terminal 40 includes a first conductive region 41 and a second conductive region 42 provided on the first surface 11. The first conductive region 41, the conductive region (not shown) provided on the sidewall of the notch part of the first side surface 12, and the conductive region 43 provided on the back surface of the insulating substrate 10 constitute a continuous region. The second conductive region 42, the conductive region (not shown) provided on the notch part of the first side surface 12, and the conductive region 44 (FIG. 2C) provided on the back surface of the insulating substrate 10 constitute a continuous region. The interconnect part such as a circuit substrate is bonded with a solder fillet. This facilitates confirming the bonding state of the solder material.

The input terminal 40 and the output terminal 50 can be made of e.g. Cu foil provided on the first surface 11 of the insulating substrate 10 and a plating layer of e.g. Ni, Pd, or Au stacked thereon.

The resin molded body 60 (shown by dashed lines in FIG. 1) is provided on the upper surface 11 of the insulating substrate 10, the input terminal 40, the output terminal 50, the semiconductor light receiving element 20, the semiconductor light emitting element 30, and the antistripping material 70. The resin molded body 60 can be made of e.g. epoxy resin.

The antistripping material 70 is provided at least on the region of the first conductive region 41 and the second conductive region 42 adjacent to the first side surface 12, the region of the third region 51 and the fourth region 52 adjacent to the second side surface 13, and the region of the first surface 11 of the insulating substrate 10 adjacent to the second side surface 13. The antistripping material 70 is located on the lower surface of the resin molded body 60. The antistripping material 70 can be made of e.g. polyimide or a silane coupling agent. The antistripping material 70 is formed between the Au plating layer on the surface of the terminal and the resin molded body 60. The antistripping material 70 enhances adhesiveness at each interface and acts as an antistripping layer. The antistripping material 70 has good adhesiveness also to the insulating substrate 10. This suppresses intrusion of e.g. oxygen, corrosive gas, chemical solution, and moisture, and can improve long-term reliability under high humidity/high temperature environments.

In these figures, the interface at which the metal terminal is in contact with the resin molded body is not exposed by dicing in the region of the upper surface 11 of the insulating substrate 10 where the input terminal 40 and the output terminal 50 are not provided. The lower surface of the resin molded body 60 made of e.g. epoxy is bonded to the upper surface 11 of the insulating substrate 10 (containing e.g. glass fiber) via the antistripping material 70. The antistripping material 70 has good adhesiveness to epoxy and glass fiber. This further suppresses stripping.

Polyimide constituting the antistripping material has a conjugate structure of aromatic groups through imide bonds. Thus, polyimide has a rigid and robust molecular structure, and the imide bond has a strong intermolecular force. This enhances adhesiveness to the insulating substrate and the resin molded body and suppresses stripping compared with conventional arts.

The silane coupling agent constituting the antistripping material includes a reaction group (such as vinyl group and epoxy group) chemically coupled to an organic material and a reaction group (such as methoxy group and ethoxy group) chemically coupled to an inorganic material in the molecule. This facilitates improving mechanical strength and adhesiveness.

In the A-A cross section shown in FIG. 2B, the input terminal 40 is not located in the region crossing the first side surface 12. Thus, the antistripping material 70 is in contact with the upper surface 11 of the insulating substrate 10. On the other hand, in the B-B cross section shown in FIG. 2C, the second region 42 is adjacent to the first side surface 12. Thus, the antistripping material 70 is in close contact with the lower surface of the resin molded body 60 and the upper surface of the input terminal 40 and acts as an antistripping layer. That is, the first side surface 12 and the second side surface 13 include a cutting surface commonly including the cross section of the terminal, the cross section of the antistripping material 70, the cross section of the resin molded body 60, and the cross section of the insulating substrate 10.

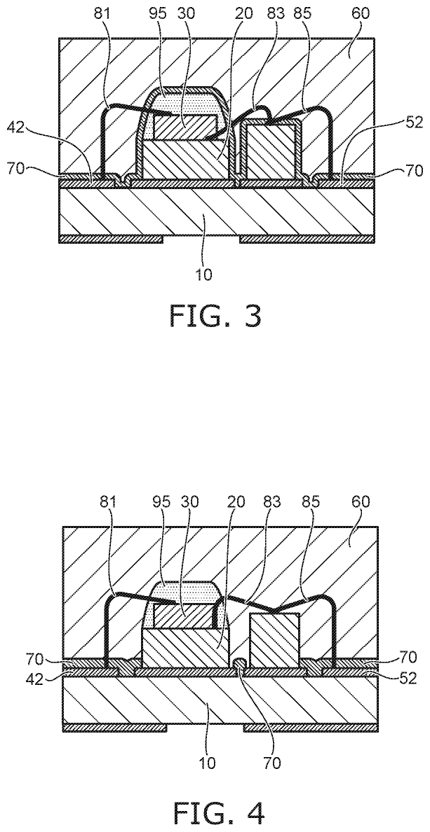

FIG. 3 is a schematic sectional view taken along line B-B illustrating a variation of the shape of the antistripping material.

Polyimidization may be performed by e.g. heating polyamic acid to 200° C. or more. Then, if the viscosity is low, polyamic acid is spread over the insulating substrate 10. This may make patterning difficult. In this case, the antistripping material 70 applied onto e.g. an exposed region of the insulating substrate 10, the semiconductor light receiving element 20, and the semiconductor light emitting element 30 is spread over the entire surface. However, this does not compromise the effect of the antistripping layer.

FIG. 4 is a schematic sectional view taken along line B-B illustrating a second variation of the shape of the antistripping material.

The antistripping material 70 is applied onto part of the upper surface 11 of the insulating substrate 10 and heated. In this case, at a viscosity of high wettability, the antistripping material 70 is spread over an exposed region of the insulating substrate 10, the input terminal and the output terminal. However, the antistripping material 70 is not formed on the semiconductor light receiving element 20 and the semiconductor light emitting element 30. Even this configuration does not compromise the effect of the antistripping layer.

A pad electrode and a paste as a mounting material are located between the semiconductor light receiving element 20 and the insulating substrate 10. The pad electrode and the paste are covered with the antistripping material 70 and form the same flat surface as the surface of the antistripping material 70 covering the upper surface 11 of the insulating substrate 10.

Alternatively, the pad electrode and the paste part as a mounting material may form protrusions different in height, and the insulating substrate 10 may form a depression. Thus, the protrusion and the depression may form one continuous plane having a gradual undulation. Furthermore, the antistripping material 70 may be configured to be thick primarily in the outer peripheral part of the insulating substrate 10 and thin inside.

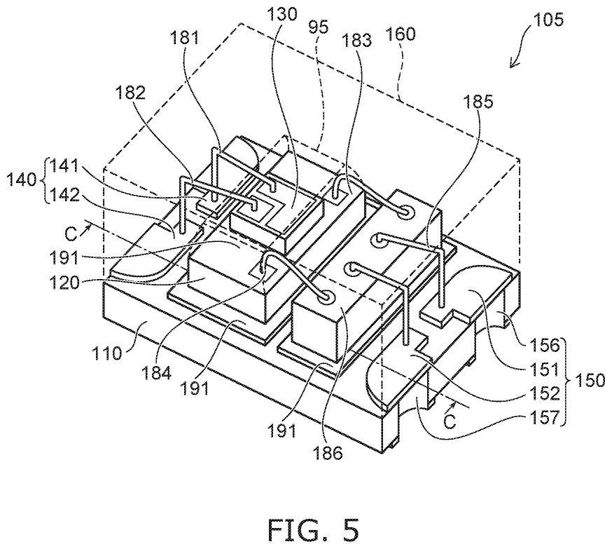

FIG. 5 is a schematic perspective view of an photocoupler according to a comparative example.

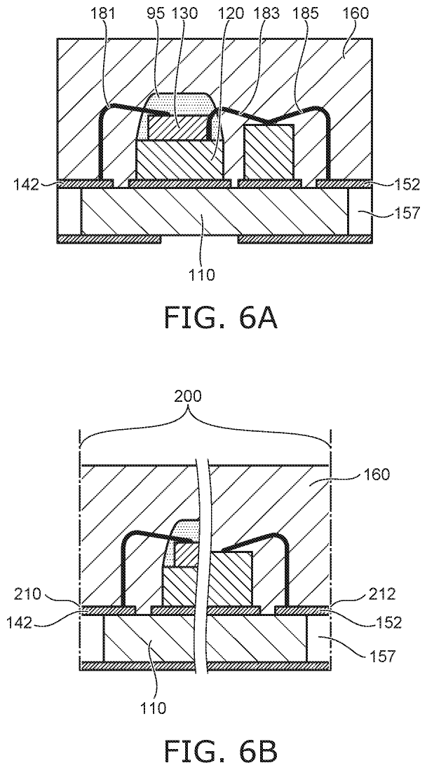

FIG. 6A is a schematic sectional view taken along line C-C of the photocoupler according to the comparative example. FIG. 6B is a partially enlarged schematic sectional view taken along line C-C.

The photocoupler 105 includes an insulating substrate 110, a semiconductor light receiving element 120, a semiconductor light emitting element 130, an input terminal 140, an output terminal 150, and a resin molded body 160. FIG. 5 shows a perspective view before forming the resin molded body 160 (shown by dashed lines).

The semiconductor light receiving element 120 and the semiconductor light emitting element 130 are bonded onto the insulating substrate 110 provided with the input terminal 140 and the output terminal 150, and are subjected to wire bonding. Then, resin molding is performed using e.g. epoxy. Up to this stage, the process is performed using a multi-piece insulating substrate. Furthermore, it is divided into individual devices by a dicing blade. In FIG. 6B, the dicing position 200 is shown at both ends of the singulated photocoupler. The thickness of the dicing blade is e.g. 0.1-0.3 mm.

In the comparative example, an interface 210 is exposed between the second region 142 of the input terminal 140 and the resin molded body 160. An interface 212 is exposed between the fourth region 152 of the output terminal and the resin molded body 160. The surface of the conductive regions 141, 142 of the input terminal 140 and the conductive regions 151, 152 of the output terminal 150 can be subjected to Au plating to enhance bonding strength with wire bonding. However, the adhesive force between the Au layer and the resin molded body 160 is very weak. Thus, external oxygen, moisture, chemical solution and the like intrude inside through the interfaces 210, 212. The degree of hermeticity can be measured by e.g. the gross leak test.

Stripping is likely to proceed inward from the outer edge of the interface. As a result, the device itself is degraded together with the electrode of the semiconductor light receiving element 120, the electrode of the semiconductor light emitting element 130, and bonding wires 181-186 under high humidity/high temperature environments. This decreases long-term reliability.

In contrast, in the first embodiment and the variations associated therewith, the antistripping material 70 acting as an antistripping layer is provided at the interface between the input terminal 40 and the resin molded body 60 and the interface between the output terminal 50 and the resin molded body 60. This suppresses stripping at the interface even under high humidity/high temperature environments and improves long-term reliability.

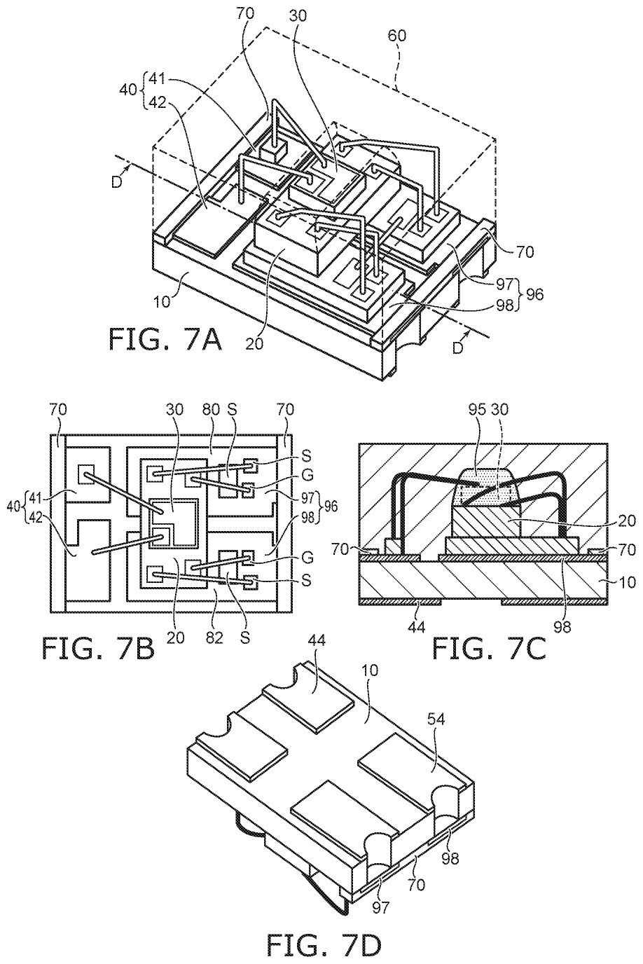

FIG. 7A is a schematic perspective view of an photocoupler according to a second embodiment. FIG. 7B is a schematic plan view before forming a sealing resin layer. FIG. 7C is a schematic sectional view taken along line D-D. FIG. 7D is a schematic bottom view.

In FIG. 7A, the resin molded body 60 is shown by dashed lines. In FIGS. 7B and 7D, the resin molded body is omitted. The third conductive region 97 of the output terminal 96 extends toward the first conductive region 41 of the input terminal. A first MOSFET chip 80 is bonded and electrically connected to the third conductive region 97. Likewise, a second MOSFET 82 is bonded and electrically connected to the fourth conductive region 98. The semiconductor light receiving element 20 is bonded astride the first MOSFET 80 and the second MOSFET 82. The semiconductor light emitting element 30 is bonded to the light receiving region of the semiconductor light receiving element 20.

Also in the second embodiment, an antistripping material 70 acting as an antistripping layer is provided at the interface between the input terminal 40 and the resin molded body 60 and the interface between the output terminal 96 and the resin molded body 60. This suppresses stripping at the interface between the electrode and the resin under high humidity/high temperature environments and improves long-term reliability in e.g. AC-load photorelays.

The first embodiment and the variations associated therewith and the second embodiment provide a photocoupler having improved adhesiveness between the output terminal and the resin molded body and enhanced reliability in high temperature/high humidity environments. As a result, the photocoupler is used to switch high-speed signals in e.g. a semiconductor tester composed of a very large number of photorelays.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A photocoupler comprising:
an insulating substrate including an upper surface, a first side surface, and a second side surface on opposite side of the first side surface;
a semiconductor light receiving element provided on the upper surface of the insulating substrate and including a light receiving region, a first electrode, and a second electrode on its upper surface;
a semiconductor light emitting element provided on the light receiving region, including a first electrode and a second electrode on its upper surface, and emitting emission light toward the light receiving region;
an input terminal including a first conductive region and a second conductive region, the first conductive region being connected to the first electrode of the semiconductor light emitting element and being in contact with the first side surface, and the second conductive region being connected to the second electrode of the semiconductor light emitting element and being in contact with the first side surface;
an output terminal including a third conductive region and a fourth conductive region, the third conductive region being connected to the first electrode of the semiconductor light receiving element and being in contact with the second side surface, and the fourth conductive region being connected to the second electrode of the semiconductor light receiving element and being in contact with the second side surface;
a resin molded body provided on the upper surface of the insulating substrate, the input terminal, the output terminal, the semiconductor light receiving element, and the semiconductor light emitting element; and
an antistripping material bonding a lower surface of the resin molded body to the input terminal and the lower surface of the resin molded body to the output terminal, a part of the first conductive region adjacent to the first side surface being bonded to the resin molded body, a part of the second conductive region adjacent to the first side surface being bonded to the resin molded body, a part of the third conductive region adjacent to the second side surface being bonded to the resin molded body, a part of the fourth conductive region adjacent to the second side surface being bonded to the resin molded body.

2. The photocoupler according to claim 1, wherein the antistripping material covers an exposed region of the upper surface of the insulating substrate, the input terminal, the output terminal, the semiconductor light receiving element, and the semiconductor light emitting element entirely on the upper surface of the insulating substrate.

3. The photocoupler according to claim 1, wherein the antistripping material covers an exposed region of the upper surface of the insulating substrate, the input terminal, and the output terminal on the upper surface of the insulating substrate.

4. The photocoupler according to claim 1, wherein the antistripping material is made of polyimide or a silane coupling agent.

5. The photocoupler according to claim 2, wherein the antistripping material is made of polyimide or a silane coupling agent.

6. The photocoupler according to claim 3, wherein the antistripping material is made of polyimide or a silane coupling agent.

7. The photocoupler according to claim 1, further comprising:
a semiconductor controlling element connected between the semiconductor light receiving element and the output terminal.

8. The photocoupler according to claim 7, wherein the semiconductor controlling element includes a MOSFET.

9. The photocoupler according to claim 7, wherein the semiconductor controlling element includes two common-source connected MOSFETs.
